(19) United States
(12) Patent Application Publication
(10) Pub. No.: US 2011/0297943 A1
(43) Pub. Date: Dec. 8, 2011

(54) ORGANIC LIGHT-EMITTING DISPLAY DEVICE AND METHOD OF MANUFACTURING THE SAME

(76) Inventors: Gun-Shik Kim, Yongin-city (KR); Jun-Sik Oh, Yongin-city (KR)

(21) Appl. No.: 13/095,701

(22) Filed: Apr. 27, 2011

(30) Foreign Application Priority Data
Jun. 3, 2010 (KR) 10-2010-0052363

(51) Int. Cl. H01L 27/32; H01L 51/56

(52) U.S. Cl. 257/59; 438/34; 257/E27.119

(57) ABSTRACT

An organic light-emitting display device including an insulating layer having an uneven portion formed in an emission area so as to reduce changes in color characteristics due to a viewing angle, and a method of manufacturing the same. The organic light-emitting display device includes: a substrate including an emission area and a circuit area including at least one thin film transistor (TFT); an insulating layer having a contact hole located at the circuit area, and including an uneven portion located at the emission area, the contact hole exposing the at least one TFT; a first electrode located on the uneven portion and coupled to the at least one TFT through the contact hole; an organic layer located on the first electrode; and a second electrode located on the organic layer.

### CROSS-REFERENCE TO RELATED PATENT APPLICATION

This application claims the benefit of Korean Patent Application No. 10-2010-0052363, filed on Jun. 3, 2010 in the Korean Intellectual Property Office, the entire disclosure of which is incorporated herein by reference.

### BACKGROUND

1. Field

Embodiments of the present invention relate to an organic light-emitting display device and a method of manufacturing the same.

2. Description of the Related Art

In general, organic light emitting display devices have a wide viewing angle, a high contrast ratio, a short response time, and reduced (or low) power consumption, and thus may be used for a variety of applications such as personal portable devices (e.g., MP3 players and mobile phones) or large screen displays (e.g., television sets).

When both an anode and a cathode included in an organic light-emitting display device are formed of a semi-transparent metal, optical interference might occur. In this case, a color may vary with an angle at which a user sees (or views) the organic light-emitting display device. In particular, in the case of a large TV, there is a large difference in color characteristics due to a viewing angle at which the user sees (or views) the large TV.

### SUMMARY

Embodiments of the present invention provide an organic light-emitting display device including an insulating layer having an uneven portion located in an emission area so as to reduce a difference in color characteristics due to a viewing angle, and a method of manufacturing the organic light-emitting display device.

According to an aspect of an embodiment of the present invention, there is provided an organic light-emitting display device including: a substrate including an emission area and a circuit area including at least one thin film transistor (TFT); an insulating layer having a contact hole located at the circuit area and including an uneven portion located at the emission area, the contact hole exposing the at least one TFT; a first electrode located on the uneven portion and coupled to the at least one TFT through the contact hole; an organic layer located on the first electrode; and a second electrode located on the organic layer.

The uneven portion may include a plurality of inclined portions located at a plurality of edges of the uneven portion and a center portion located at a center of the uneven portion, an area of the inclined portions may be 40% to 60% of a total area of the uneven portion, and an area of the center portion may be 60% to 40% of the total area of the uneven portion.

Each of the inclined portions may include an inclined surface with an angle of 15° to 30° with respect to the substrate, and the center portion may include an inclined surface with an angle that is equal to or less than 10° with respect to the substrate.

The uneven portion may have a trapezoidal shape having a protruding cross-section.

The uneven portion may have a reverse-trapezoidal shape having a depressed cross-section.

The uneven portion may have a convex curve-shape, wherein an inclination angle of a cross-section of the uneven portion decreases from the edges toward the center of the uneven portion.

The uneven portion may have a concave curve-shape, wherein an inclined angle of a cross-section of the uneven portion decreases from the edges to the center of the uneven portion.

The insulating layer may include a plurality of uneven portions located at the emission area.

The first electrode, the organic layer, and the second electrode may have a substantially uniform thickness.

The uneven portion may be a protruding portion or a depressed portion.

According to another aspect of an embodiment of the present invention, there is provided a method of manufacturing an organic light-emitting display device, the method including: defining an emission area and a circuit area on a substrate; forming a thin film transistor (TFT) at the circuit area; forming an insulating layer at the emission area and the circuit area in which the TFT is located, so that an uneven portion is located in a portion corresponding to the emission area; forming a contact hole to expose the TFT at the circuit area; forming a first electrode on the uneven portion, the first electrode being coupled to the thin film transistor through the contact hole; forming an organic layer on the first electrode; and forming a second electrode on the organic layer.

The uneven portion may include inclined portions located at edges of the uneven portion and a center portion located at a center of the uneven portion, an area of the inclined portions may be 40% to 60% of a total area of the uneven portion, and an area of the center portion may be 60% to 40% of the total area of the uneven portion.

Each of the inclined portions may include an inclined surface with an angle of 15° to 30° with respect to the substrate, and the center portion may include an inclined surface with an angle that is equal to or less than 10° with respect to the substrate.

The uneven portion may have a trapezoidal shape having a protruding cross-section.

The uneven portion may have a reverse-trapezoidal shape having a depressed cross-section.

The uneven portion may have a convex curve-shape, wherein an inclination angle of a cross-section of the uneven portion decreases from the edges toward the center of the uneven portion.

The uneven portion may have a concave curve-shape, wherein an inclination angle of a cross-section of the uneven portion decreases from the edges toward the center of the uneven portion.

The method may further include forming a plurality of uneven portions in the emission area.

The uneven portion may be a protruding portion or a depressed portion.

### BRIEF DESCRIPTION OF THE DRAWINGS

The above and other features and aspects of the present invention will become more apparent by describing in detail exemplary embodiments thereof with reference to the attached drawings in which:

FIG. 1 is a plan view of an organic light-emitting display device including red pixels, green pixels, and blue pixels adjacent to one another, according to an embodiment of the present invention;

FIG. 2 is a cross-sectional view of the organic light-emitting display device taken along a line II-II′ of FIG. 1;

FIG. 3 is a detailed cross-sectional view of an example of an uneven portion of an organic light emitting element EL of FIG. 2;

FIGS. 4 through 10 are detailed cross-sectional views of other embodiments of an uneven portion of the organic light emitting element EL of FIG. 2; and

FIG. 11 is a cross-sectional view of the organic light-emitting display device taken along a line III-III′ of FIG. 1.

### DETAILED DESCRIPTION

As the invention allows for various changes and numerous embodiments, particular embodiments will be illustrated in the drawings and described in detail in the written description. However, this is not intended to limit the present invention to particular modes of practice, and it is to be appreciated that all changes, equivalents, and substitutes that do not depart from the spirit and technical scope of the present invention are encompassed in the present invention. In the following description of embodiments of the present invention, details of related well-known technologies will not be provided if they are deemed unnecessary and make features of the invention obscure.

While such terms as “first,” “second,” etc., may be used to describe various components, such components must not be limited to the above terms. The above terms are used only to distinguish one component from another.

The terms used in the present specification are merely used to describe particular embodiments, and are not intended to limit the present invention. An expression used in the singular encompasses the expression of the plural, unless it has a clearly different meaning in the context. In the present specification, it is to be understood that terms such as “including” or “having,” etc., are intended to indicate the existence of features, numbers, steps, actions, components, parts, or combinations thereof disclosed in the specification, and are not intended to preclude the possibility that one or more other features, numbers, steps, actions, components, parts, or combinations thereof may exist or may be added.

Embodiments of the present invention will now be described more fully with reference to the accompanying drawings in which exemplary embodiments of the invention are shown.

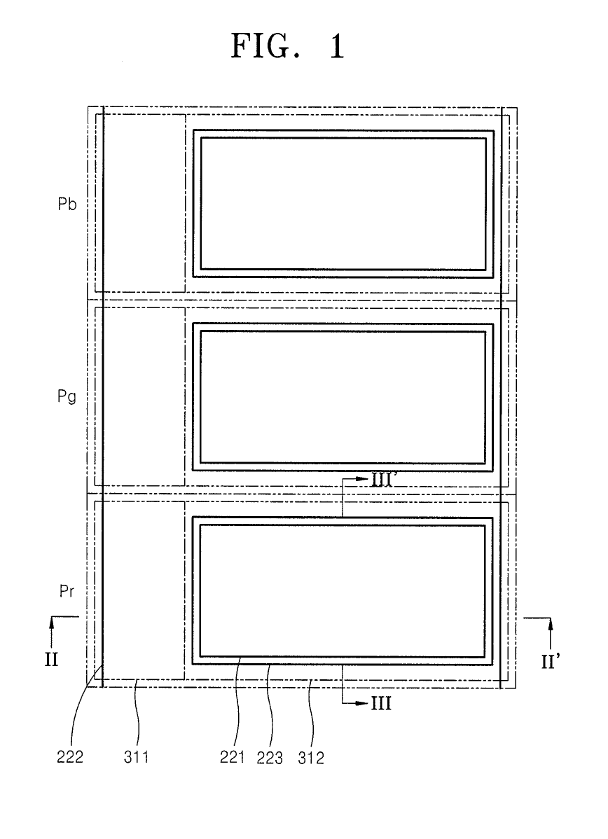

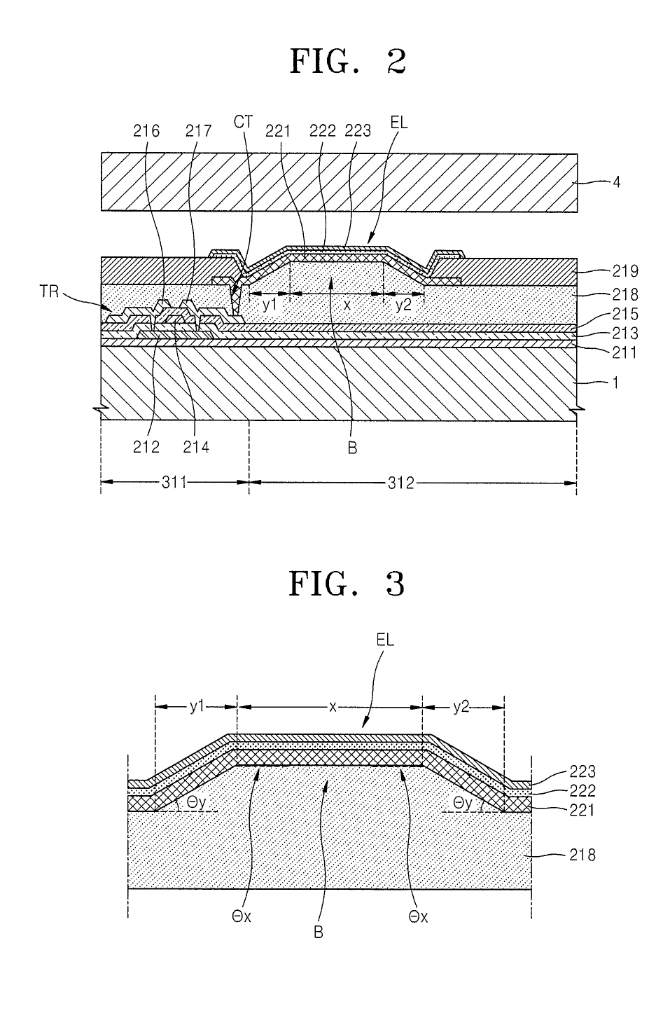

FIG. 1 is a plan view of an organic light-emitting display device including red pixels Pr, green pixels Pg, and blue pixels Pb adjacent to one another, according to an embodiment of the present invention, and FIG. 2 is a cross-sectional view of the organic light-emitting display device taken along a line II-II′ of FIG. 1.

Each of the red pixels Pr, the green pixels Pg, and the blue pixels Pb includes a circuit area 311 and an emission area 312. The circuit area 311 and the emission area 312 are adjacent to each other. In FIG. 1, each emission area 312 extends in a widthwise direction, and each of the red pixels Pr, the green pixels Pg, and the blue pixels Pb are arranged in a lengthwise direction. However, embodiments of the present invention are not limited thereto. Each emission area 312 may extend in the lengthwise direction, and each of the red pixels Pr, the green pixels Pg, and the blue pixels Pb may be arranged in the widthwise direction. The shape and arrangement structure of the emission area 312 and each of the pixels Pr, the green pixels Pg, and the blue pixels Pb may be implemented by one of ordinary skill in the art in various ways.

As illustrated in FIG. 2, according to one embodiment of the present invention, a pixel circuit includes a thin film transistor (TFT) TR located in the circuit area 311. The pixel circuit is not limited to a pixel circuit including one TFT TR as illustrated in FIG. 2. The pixel circuit may further include a plurality of TFTs and a plurality of storage capacitors as well as the TFT TR, and wirings, such as a scan line, a data line, and a Vdd line, may be electrically coupled to the pixel circuit.

An organic light emitting element EL as an emission device is located in the emission area 312. The organic EL device is electrically coupled to the TFT TR of the pixel circuit.

A buffer layer 211 is formed on a substrate 1, and the pixel circuit including the TFT TR is formed on the buffer layer 211.

First, a semiconductor active layer 212 is formed on the buffer layer 211.

The buffer layer 211, which is formed of a transparent insulating material, prevents impurity elements from penetrating into the organic light emitting element EL and planarizes a surface of the organic light emitting element EL. The buffer layer 211 may be formed of any of various materials that can perform the functions described above. For example, an inorganic material such as silicon oxide, silicon nitride, silicon oxynitride, aluminum oxide, aluminum nitride, titanium oxide, or titanium nitride, an organic material such as polyimide, polyester, or acryl, or stacks of these materials. In some embodiments, the buffer layer 211 may be omitted.

The semiconductor active layer 212 may be formed of polycrystalline silicon (or polysilicon), but is not limited thereto, and may be formed of a semiconductor oxide such as, a G—I—Z—O layer [(In₂O₃)ₐ(Ga₂O₃)_{b}(ZnO)_{c} layer], wherein a, b, and c are integers that respectively satisfy the conditions a≧0, b≧0, and c>0.

A gate insulating layer 213 is formed on the buffer layer 211 to cover the semiconductor active layer 212. A gate electrode 214 is formed on the gate insulating layer 213.

An interlayer insulating layer 215 is formed on the gate insulating layer 213 to cover the gate electrode 214, and a source electrode 216 and a drain electrode 217 are formed on the interlayer insulating layer 215 and contact each other through the semiconductor active layer 212. A contact hole CT also exposes a portion of the drain electrode 217.

The structure of the TFT TR is not limited to the above description, and any of the various types of TFT structures may be employed.

An insulating layer 218 is formed to cover the TFT TR. The insulating layer 218 may be formed as a single- or multi-layered stack structure. The insulating layer 218 may be formed of an inorganic material and/or an organic material.

The insulating layer 218 according to an embodiment of the present invention includes the contact hole CT formed in the circuit area 311 and exposing the TFT TR, and an uneven portion B formed in the emission area 312. The uneven portion B may include inclined portions y1 and y2 at edges thereof, and a center portion x at the center thereof. The edges of the uneven portion B may be adjacent to a pixel defining layer (PDL) 219, and the center (x) of the uneven portion B may be farther away from the PDL 219 than the inclined portions (y1 and y2).

FIG. 3 is a detailed cross-sectional view of an example of the uneven portion B of the organic light emitting element EL of FIG. 2.

According to an embodiment of the present invention, the area of the inclined portions y1 and y2 may be 40% to 60% of the entire area of the uneven portion B, and the area of the center portion x may be 60% to 40% of the entire area of the uneven portion B. When the ratio of the area of the inclined portions y1 and y2 to the area of the center portion x is 50:50, color characteristics may be relatively stable according to a viewing angle (or across viewing angles) without lowering vertical brightness. As illustrated in FIG. 3, the area of the inclined portions y1 and y2 is (y1+y2), and the area of the center portion x is x.

When the area of the inclined portions y1 and y2 is less than 40% of the total area of the uneven portion B or the area of the center portion x is greater than 60% of the total area of the uneven portion B, the area of the inclined portions y1 and y2 is small and heights of the inclined portions y1 and y2 are reduced. Thus, the color characteristics may still vary with a viewing angle. In particular, when an angle of an inclined surface of the inclined portions y1 and y2 is 15° to 30° with respect to the substrate 1, a change of color and/or brightness with all viewing angles may not be sufficiently compensated for.

Also, when the area of the inclined portions y1 and y2 is greater than 60% of the total area of the uneven portion B or the area of the center portion x is less than 40% of the total area of the uneven portion B, vertical brightness may be rapidly lowered (or decreased). Vertical brightness is defined as the brightness of a perpendicular surface and is an index that indicates the efficiency of a device. When vertical brightness is lowered (or decreased), power consumption of the organic light-emitting display device of FIG. 1 may be greatly increased (e.g., in order to achieve acceptable brightness).

According to an embodiment of the present invention, each of the inclined portions y1 and y2 may be characterized by an angle of 15° to 30° with respect to the substrate 1, and the center portion x may be characterized by an angle of 0° to 10° with respect to the substrate 1. As illustrated in FIG. 3, an angle of each of the inclined portions y1 and y2 is θy, and an angle of the center portion x is θx. In this regard, the angle θy of each of the inclined portions y1 and y2 and the angle ex of the center portion x are determined based on the surface of the insulating layer 218 in which the uneven portion B is not formed, as illustrated in FIG. 3.

When the angle θy of each of the inclined portions y1 and y2 is less than 15° with respect to the substrate 1, the color characteristics may still vary with a viewing angle, and when the angle θy of each of the inclined portions y1 and y2 is greater than 30° with respect to the substrate 1, vertical brightness may decrease. Thus, the angle θy of each of the inclined portions y1 and y2 should be 15° to 30° with respect to the substrate 1 in order to obtain substantially uniform color characteristics regardless of a viewing angle (or across viewing angles) and to maintain high vertical brightness, e.g., to improve the efficiency of a device. The center portion x may include an inclined surface at an angle that is equal to or less than 10° with respect to the substrate 1. In this regard, the lower-limit value of the angle θx of the center portion x may be 0°. Experimentally, when the angle ex of the center portion x is greater than 10° with respect to the substrate 1, the color and/or the brightness of the display may vary across viewing angles including a front view.

In FIG. 2, the uneven portion B has a trapezoidal cross-section that protrudes in a direction toward an encapsulation substrate 4. In more detail, the ratio of the area of the inclined portions y1 and y2 to the area of the center portion x is 50:50, and an inner angle of a trapezoid which is equal to the angle θy of the inclined portions y1 and y2 is 30° with respect to the substrate 1, and the center portion x may be completely flat. However, the shape of the uneven portion B is not limited to the above description, and the uneven portion B may have various other shapes than the above-mentioned shape.

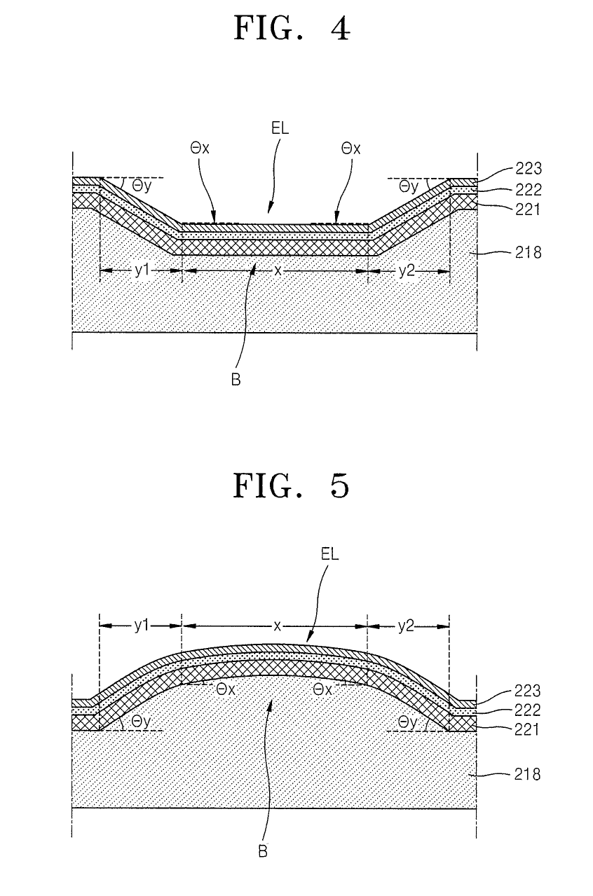

FIGS. 4 through 10 are detailed cross-sectional views of another example of the uneven portion B of the organic light emitting element EL of FIG. 2.

Referring to FIG. 4, the uneven portion B may be a reverse-trapezoid having a cross-section depressed in a direction toward a substrate 1. In this embodiment, the area of the inclined portions y1 and y2 may be 40% to 60% of the area of the uneven portion B, and the area of the center portion x may be 60% to 40% of the area of the uneven portion B. Also, the angle θy of each of the inclined portions y1 and y2 may be 15° to 30° with respect to the substrate 1, and the center portion x may have a flat surface without any inclination.

Referring to FIG. 5, the uneven portion B may have an inclination angle of a cross-section that decreases from edges to a center of the uneven portion B and may be convex curve-shaped in a direction toward the encapsulation substrate 4. In this embodiment, the area of the inclined portions y1 and y2 may be 40% to 60% of the area of the uneven portion B, and the area of the center portion x may be 60% to 40% of the area of the uneven portion B. Also, the angle By of each of the inclined portions y1 and y2 may be 15° to 30° with respect to the substrate 1, and the center portion x may include an inclined surface with an angle θx that is equal to or less than 10° with respect to the substrate 1.

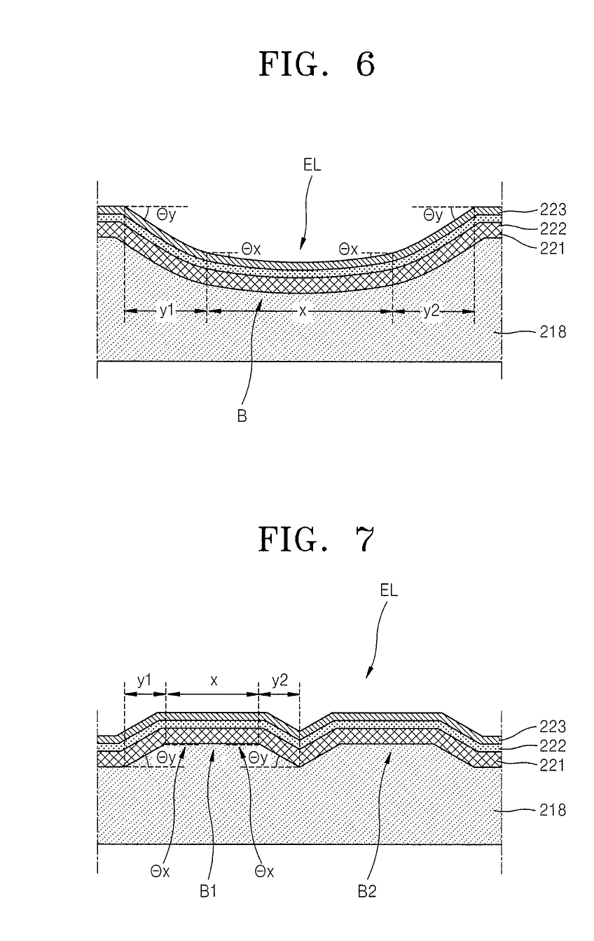

Referring to FIG. 6, the uneven portion B may have an inclination angle of a cross-section that decreases from edges to a center of the uneven portion B and may be concave curve-shaped that is depressed in the direction toward the substrate 1. In this embodiment, the area of the inclined portions y1 and y2 may be 40% to 60% of the area of the uneven portion B, and the area of the center portion x may be 60% to 40% of the area of the uneven portion B. Also, the angle θy of each of the inclined portions y1 and y2 may be 15° to 30° with respect to the substrate 1, and the center portion x may include an inclined surface with an angle θx that is equal to or less than 10° with respect to the substrate 1.

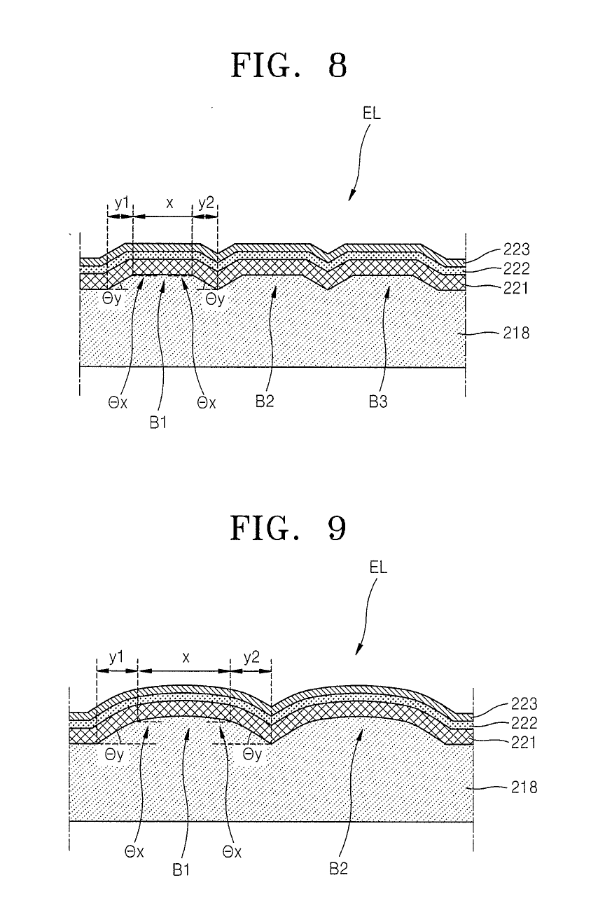

Referring to FIGS. 7 and 8, a plurality of uneven portions may be formed in the insulating layer 218. In FIG. 7, two uneven portions, such as a first uneven portion B1 and a second uneven portion B2, are illustrated. Each of the first and second uneven portions B1 and B2 has the same shape as that of the uneven portion B of FIG. 3 and may be different in size from the uneven portion B. In FIG. 8, three uneven portions, such as a first uneven portion B1, a second uneven portion B2, and a third uneven portion B3, are illustrated. Each of the first through third uneven portions B1, B2, and B3 has the same shape as that of the uneven portion B of FIG. 3 and may be different in size from the uneven portion B. The number of uneven portions B is not limited thereto, and four or more uneven portions B may be formed. Each of the first through third uneven portions B1, B2, and B3 includes the inclined portions y1 and y2 and the center portion x. The area of the inclined portions y1 and y2 may be 40% to 60% of the area of the uneven portion B, and the area of the center portion x may be 60% to 40% of the area of the uneven portion B. Also, the angle θy of the inclined portions y1 and y2 may be 15° to 30° with respect to the substrate 1, and the center portion x may be a flat surface.

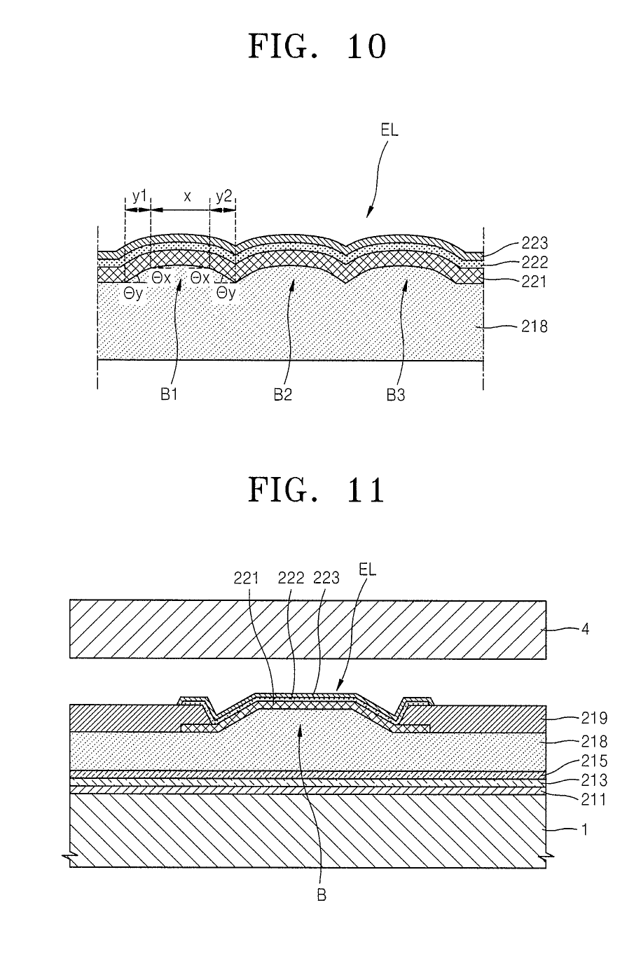

Referring to FIGS. 9 and 10, a plurality of uneven portions may be formed in the insulating layer 218. In FIG. 9, two uneven portions, such as a first uneven portion B1 and a second uneven portion B2, are illustrated. Each of the first and second uneven portions B1 and B2 has the same shape as that of the uneven portion B of FIG. 5 and may be different in size from the uneven portion B. In FIG. 10, three uneven portions, such as a first uneven portion B1, a second uneven portion B2, and a third uneven portion B3, are illustrated. Each of the first through third uneven portions B1, B2, and B3 has the same shape as that of the uneven portion B of FIG. 5 and may be different in size from the uneven portion B. The number of uneven portions is not limited thereto, and two or four or more uneven portions B may be formed. In one embodiment, each of the first through third uneven portions B1, B2, and B3 includes the inclined portions y1 and y2 and the center portion x. The area of the inclined portions y1 and y2 may be 40% to 60% of the total area of the uneven portions B1, B2, and B3, and the area of the center portion x may be 60% to 40% of the total area of the uneven portions B1, B2, and B3. Also, the angle θy of each of the inclined portions y1 and y2 may be 15° to 30° with respect to the substrate 1, and the center portion x may include an inclined surface with an angle θx that is equal to or less than 10° with respect to the substrate 1.

According to one embodiment of the present invention, a plurality of uneven portions having the shape of FIGS. 4 and 6 may be formed in the insulating layer 218 in the emission area 312. When the plurality of uneven portions B1, B2, and B3 are formed, as illustrated in FIGS. 7 through 10, the frequency of occurrence of the inclined portions y1 and y2 in one pixel increases so that the problem related to the color characteristics that vary according to a viewing angle may be efficiently reduced or solved.

A first electrode 221, an organic layer 222, and a third electrode 223 are sequentially formed on the uneven portion B to a uniform thickness. A more detailed description of the first electrode 221, the organic layer 222, and the second electrode 223 will be provided later.

The first electrode 221 of the organic EL device electrically coupled to the TFT TR, as illustrated in FIG. 3, is formed on the insulating layer 218. The first electrode 221 is formed in an independent island shape according to all pixels.

The first electrode 221 may be formed of a material having a high work function, such as indium tin oxide (ITO), indium zinc oxide (IZO), zinc oxide (ZnO), or indium oxide (In₂O₃). For a top-emission organic light-emitting display device that displays an image in a direction opposite to the substrate 1 in FIG. 1, the first electrode 221 may further include a reflection layer that is formed of a material selected from the group consisting of silver (Ag), magnesium (Mg), aluminum (Al), platinum (Pt), palladium (Pd), gold (Au), nickel (Ni), neodymium (Nd), iridium (Ir), chromium (Cr), lithium (Li), and calcium (Ca).

The pixel defining layer (PDL) 219 is formed on the insulating layer 218.

In one embodiment of the present invention, the PDL 219 covers edges of the first electrode 221 and exposes a middle portion thereof. The PDL 219 may cover the edges of the first electrode 221.

According to one embodiment of the present invention, the PDL 219 is formed of an organic insulating material, such as acryl-based resin or epoxy-based resin or a polymer-based organic material, such as polyimide. The top surface of the PDL 219 may be flat.

The organic layer 222 is formed on the first electrode 221 exposed through the PDL 219.

The organic layer 222 may be a low molecular weight organic film or a polymer organic film. The organic layer 222 may be formed as a single- or multi-layered stack structure including at least one layer selected from the group consisting of a hole injection layer (HIL), a hole transport layer (HTL), an emission layer (EML), an electron transport layer (ETL) and an electron injection layer (EIL). In this regard, EMLs are deposited to be separated from one another according to colors of pixels, and the other layers are commonly applied to all of the pixels.

The HIL may be formed of a phthalocyanine compound, such as copper phthalocyanine, or TCTA, m-MTDATA, m-MTDAPB, and the like that are starburst type amines. The HTL may be formed of N,N′-bis(3-methylphenyl)-N,N′-diphenyl-[1,1-biphenyl]-4,4′-diamine (TPD), N,N′-di(naphthalene-1-yl)-N,N′-diphenyl benzidin (α-NPD), and the like.

The EIL may be formed using a material selected from the group consisting of LiF, NaCl, CsF, Li₂O, BaO, and Liq. The ETL may be formed using Alq₃.

The EML may include a host material and a dopant material. Examples of the host material may include tris(8-hydroxy-quinolinato)aluminum (Alq3), 9,10-di(naphth-2-yl)anthracene (AND), 3-tert-butyl-9,10-di(naphth-2-yl)anthracene (TBADN), 4,4′-bis(2,2-diphenyl-ethene-1-yl)-4,4′-dimethylphenyl (DPVBi), 4,4′-bis(2,2-diphenyl-ethene-1-yl)-4,4′-dimethylphenyl (p-DMDPVBi), tert(9,9-diarylfluorene)s (TDAF), 2-(9,9′-spirobifluorene-2-yl)-9,9′-spirobifluorene (BSDF), 2,7-bis(9,9′-spirobifluorene-2-yl)-9,9′-spirobifluorene (TSDF), bis(9,9-diarylfluorene)s (BDAF), 4,4′-bis(2,2-diphenyl-ethene-1-yl)-4,4′-di-(tert-butyl)phenyl (p-TDPVBi), 1,3-bis(carbazol-9-yl)benzene (mCP), 1,3,5-tris(carbazol-9-yl)benzene (tCP), 4,4′,4″-tris(carbazol-9-yl)triphenylamine (TcTa), 4,4′-bis(carbazol-9-yl)biphenyl (CBP), 4,4′-bis(9-carbazolyl)-2,2′-dimethyl-biphenyl (CBDP), 4,4′-bis(carbazol-9-yl)-9,9-dimethyl-fluorene (DMFL-CBP), 4,4′-bis(carbazol-9-yl)-9,9-bis(9-phenyl-9H-carbazol)fluorene (FL-4CBP), 4,4′-bis(carbazol-9-yl)-9,9-di-tolyl-fluorene (DPFL-CBP), 9,9-bis(9-phenyl-9H-carbazol)fluorene (FL-2CBP), and the like.

The second electrode 223 is formed on the above-described organic layer 222. The second electrode 223 may be formed of a metal having a low work function such as silver (Ag), magnesium (Mg), aluminum (Al), platinum (Pt), palladium (Pd), gold (Au), nickel (Ni), neodymium (Nd), iridium (Ir), chromium (Cr), lithium (Li), or calcium (Ca). For example, the second electrode 223 may be formed of a metal such as Mg or Mg alloy. The first electrode 221 may function as an anode, and the second electrode 223 may function as a cathode. Alternatively, the first electrode 221 may function as a cathode, and the second electrode 223 may function as an anode.

For a bottom-emission organic light-emitting display device that displays an image in a direction toward the substrate 1, the first electrode 221 may be a transparent electrode, and the second electrode 223 may be a reflection electrode. For a top-bottom organic light-emitting display device that displays an image in a direction to the second electrode 223, the first electrode 221 may be a reflection electrode, and the second electrode 223 may be a transparent electrode. For dual-emission organic light-emitting display device, both the first electrode 221 and the second electrode 223 may be transparent electrodes.

FIG. 11 is a cross-sectional view of the organic light-emitting display device taken along a line III-III′ of FIG. 1. In the embodiment shown in FIG. 11, the uneven portion B may be formed like when the organic light-emitting display device is cut in a direction III-III′ (e.g., the cross-sectional shape of the uneven portion B along line III-III′ of FIG. 1 may be similar to the cross-sectional shape of the uneven portion along line II-II′ of FIG. 1). Since the uneven portion B according to the embodiments of the present invention is formed to have a cubic shape, the problem related to the color characteristics that vary according to a viewing angle may be reduced or solved.

A method of manufacturing the organic light-emitting display device of FIG. 1 described above according to one embodiment of the present invention will be described as follows. First, the emission area 312 and the circuit area 311 are defined on the substrate 1. Next, as described above, the TFT TR is formed in the circuit area 311, and the insulating layer 218 is formed in the circuit area 311 where the TFT TR is formed, and in the emission area 312 so that the uneven portion B may be formed in a portion corresponding to the emission area 312. Here, the uneven portion B may be formed by patterning the insulating layer 218, and the shape of the uneven portion B has been described in detail with reference to FIGS. 3 through 10. Next, the contact hole CT is formed in the circuit area 311 to expose the TFT TR, and the first electrode 221, the organic layer 222, and the second electrode 223 that are coupled to the TFT TR through the contact hole CT are sequentially formed on the uneven portion B.

According to embodiments of the present invention, the cubic uneven portion B is formed in the insulating layer 218 so that a problem related to color characteristics that vary according to a viewing angle without lowering vertical brightness may be reduced or solved. In particular, since the uneven portion B is formed in the emission area 312 according to each of the red pixels Pr, the green pixels Pg, and the blue pixels Pb, a change of color according to all viewing angles in each of the red pixels Pr, the green pixels Pg, and the blue pixels Pb may be adjusted so as to reduce or minimize a change of white color. Thus, the user can view an image on a screen with substantially uniform image over a range of viewing angles.

In an organic light-emitting display device according to embodiments of the present invention, an insulating layer having an uneven portion formed in an emission area is formed so that, even when a user views the organic light-emitting display device from sides, the user sees substantially the same color characteristics as when the user views the organic light-emitting display device from a front side. This is because an inclined surface is formed in the uneven portion and even when the user views the organic light-emitting display device from sides, light is emitted in a direction perpendicular to a surface and toward the user, like when the user views the organic light-emitting display device from the front side. Thus, the user can view a screen (or image) with substantially uniform quality across (or at) multiple viewing angles.

While the present invention has been particularly shown and described with reference to exemplary embodiments thereof, it will be understood by those of ordinary skill in the art that various changes in form and details may be made therein without departing from the spirit and scope of the present invention as defined by the following claims and equivalents thereof.

What is claimed is:

1. An organic light-emitting display device comprising:
a substrate comprising an emission area and a circuit area comprising at least one thin film transistor (TFT);
an insulating layer having a contact hole located at the circuit area and comprising an uneven portion located at the emission area, the contact hole exposing the at least one thin film transistor;
a first electrode located on the uneven portion and coupled to the at least one TFT through the contact hole;
an organic layer located on the first electrode; and
a second electrode located on the organic layer.

2. The organic light-emitting display device of claim 1, wherein
the uneven portion comprises a plurality of inclined portions located at a plurality of edges of the uneven portion and a center portion located at a center of the uneven portion,
an area of the inclined portions is 40% to 60% of a total area of the uneven portion, and
an area of the center portion is 60% to 40% of the total area of the uneven portion.

3. The organic light-emitting display device of claim 2, wherein each of the inclined portions comprises an inclined surface with an angle of 15° to 30° with respect to the substrate, and the center portion comprises an inclined surface with an angle that is equal to or less than 10° with respect to the substrate.

4. The organic light-emitting display device of claim 3, wherein the uneven portion has a trapezoidal shape having a protruding cross-section.

5. The organic light-emitting display device of claim 3, wherein the uneven portion has a reverse-trapezoidal shape having a depressed cross-section.

6. The organic light-emitting display device of claim 3, wherein the uneven portion has a convex curve shape, wherein an inclination angle of a cross-section of the uneven portion decreases from the edges toward the center of the uneven portion.

7. The organic light-emitting display device of claim 3, wherein the uneven portion has a concave curve shape, wherein an inclination angle of a cross-section of the uneven portion decreases from the edges toward the center of the uneven portion.

8. The organic light-emitting display device of claim 2, wherein the insulating layer comprises a plurality of uneven portions located at the emission area.

9. The organic light-emitting display device of claim 1, wherein the first electrode, the organic layer, and the second electrode have a substantially uniform thickness.

10. The organic light-emitting display device of claim 1, wherein the uneven portion is a protruding portion or a depressed portion.

11. A method of manufacturing an organic light-emitting display device, the method comprising:
defining an emission area and a circuit area on a substrate;
forming a thin film transistor (TFT) at the circuit area;
forming an insulating layer at the emission area and the circuit area in which the TFT is formed, so that an uneven portion is formed at a portion corresponding to the emission area;
forming a contact hole to expose the TFT at the circuit area;
forming a first electrode on the uneven portion, the first electrode being coupled to the TFT through the contact hole;
forming an organic layer on the first electrode; and
forming a second electrode on the organic layer.

12. The method of claim 11, wherein:
the uneven portion comprises inclined portions located at edges of the uneven portion and a center portion located at center of the uneven portion;
an area of the inclined portions is 40% to 60% of a total area of the uneven portion; and
an area of the center portion is 60% to 40% of the total area of the uneven portion.

13. The method of claim 12, wherein each of the inclined portions comprises an inclined surface with an angle of 15° to 30° with respect to the substrate, and the center portion comprises an inclined surface with an angle that is equal to or less than 10° with respect to the substrate.

14. The method of claim 13, wherein the uneven portion has a trapezoidal shape having a protruding cross-section.

15. The method of claim 13, wherein the uneven portion has a reverse-trapezoidal shape having a depressed cross-section.

16. The method of claim 13, wherein the uneven portion has a convex curve shape, wherein an inclination angle of a cross-section of the uneven portion decreases from the edges toward the center of the uneven portion.

17. The method of claim 13, wherein the uneven portion has a concave curve shape, wherein an inclination angle of a cross-section of the uneven portion decreases from the edges toward the center of the uneven portion.

18. The method of claim 13, further comprising forming a plurality of uneven portions located at the emission area.

19. The method of claim 11, further comprising forming the first electrode, the organic layer, and the second electrode to have a substantially uniform thickness.

20. The method of claim 11, wherein the uneven portion is a protruding portion or a depressed portion.
